(19) United States
(12) Patent Application Publication
(10) Pub. No.: US 2025/0008757 A1
(43) Pub. Date: Jan. 2, 2025

(54) DISPLAY SUBSTRATE AND METHOD FOR MANUFACTURING SAME, AND DISPLAY APPARATUS

(71) Applicant: BOE Technology Group Co., Ltd., Beijing (CN)

(72) Inventors: Jing WANG, Beijing (CN); Hongwei TIAN, Beijing (CN); Ran LI, Beijing (CN); Shantao CHEN, Beijing (CN)

(21) Appl. No.: 18/291,905

(22) PCT Filed: May 30, 2023
(86) PCT No.: PCT/CN2023/097074

§ 371 Date: Sep. 11, 2024

(30) Foreign Application Priority Data
Jun. 21, 2022 (CN) 202210704395.8

(51) Int. Cl. H10K 39/34; H10K 59/12; H10K 59/121; H10K 59/124; H10K 59/80

(52) U.S. Cl. CPC H10K 39/34; H10K 59/1201; H10K 59/1213; H10K 59/124; H10K 59/80515

(57) ABSTRACT

The present disclosure provides a display substrate and a method for manufacturing the same, and a display apparatus, belonging to the field of displaying technologies. The display substrate includes a base substrate, and a circuit layer, and has an island area, a hole area and a bridge area. The circuit layer includes a driving circuit located in the island area, a via hole located in the hole area, and at least one photoelectric sensor that is electrically connected to the driving circuit. The photoelectric sensor includes a first electrode layer, a photoelectric structure layer and a second electrode layer which are laminated. The photoelectric sensor is located in the island area or the bridge area.

The present application is a National Stage of International Application No. PCT/CN2023/097074 filed on May 30, 2023, which claims priority to Chinese Patent Application No. 202210704395.8 filed on Jun. 21, 2022, the contents of both of which are incorporated herein by reference in their entirety.

### TECHNICAL FIELD

The present disclosure relates to the field of display technologies, and more particularly, to a display substrate and a method for manufacturing the same, and a display apparatus.

### BACKGROUND OF THE INVENTION

Organic-photo-diodes (OPDs) are integrated into the display apparatus, and the OPDs detect the change of illumination in an application environment to determine the current status of the display apparatus. Taking “electronic skin” as an example, the OPDs detect the change of illumination when the display apparatus is stretched, and determine the state of stretching of the display apparatus, and then determine the state of change of human skin. However, the traditional OPD integration method occupies a large display area of the display apparatus, which reduces an opening ratio of the display apparatus, and thus reduces the overall resolution of the display apparatus.

### SUMMARY OF THE INVENTION

The present disclosure provides a display substrate and a method for manufacturing the same, and a display apparatus.

In a first aspect, an embodiment of the present disclosure provides a display substrate. The display substrate includes a base substrate, and a circuit layer disposed on the base substrate, and has an island area, a hole area and a bridge area;
the circuit layer includes a driving circuit located in the island area, and a via hole located in the hole area; the circuit layer further includes at least one photoelectric sensor that is electrically connected to the driving circuit; the photoelectric sensor includes a first electrode layer, a photoelectric structure layer and a second electrode layer which are laminated; and
the photoelectric sensor is located in the island area, and the first electrode layer, the photoelectric structure layer and the second electrode layer of the photoelectric sensor are sequentially disposed in a direction pointing from the island area to the bridge area; and/or the photoelectric sensor is located in the bridge area, and the first electrode layer, the photoelectric structure layer and the second electrode layer of the photoelectric sensor are sequentially disposed in a direction pointing from the bridge area to the island area.

In some examples, the driving circuit includes a first thin-film transistor configured to drive the photoelectric sensor, and a drain of the first thin-film transistor is electrically connected to the first electrode layer of the photoelectric sensor.

In some examples, the drain of the first thin-film transistor is multiplexed as the first electrode layer.

In some examples, the driving circuit includes a first thin-film transistor configured to drive the photoelectric sensor, and a gate of the first thin-film transistor is electrically connected to the first electrode layer of the photoelectric sensor.

In some examples, the gate of the first thin-film transistor is multiplexed as the first electrode layer.

In some examples, a light-emitting device is disposed on a side of the circuit layer away from the base substrate; the light-emitting device includes a third electrode layer, a fourth electrode layer, and a light-emitting layer disposed between the third electrode layer and the fourth electrode layer; and
the third electrode layer is multiplexed as the first electrode layer of the photoelectric sensor, and the fourth electrode layer is multiplexed as the second electrode layer of the photoelectric sensor.

In some examples, the photoelectric sensor is located in the island area, and the circuit layer includes a first thin-film transistor located in the island area, and a buffer layer, a first insulator layer, a second insulator layer and a third insulator layer which are located in the island area and sequentially disposed on the base substrate;
the first thin-film transistor includes an active layer, a gate, a source and a drain; the active layer is disposed on a side of the buffer layer away from the base substrate; the first insulator layer is disposed on a side of the buffer layer away from the base substrate and covers the active layer of the first thin-film transistor; the gate of the first thin-film transistor is disposed on a side of the first insulator layer away from the base substrate, and orthographic projections of the gate of the first thin-film transistor and the active layer of the first thin-film transistor on the base substrate are at least partially overlapped; the source and the drain of the first thin-film transistor are disposed on a side of the second insulator layer away from the base substrate, the source is electrically connected to a source area of the active layer through a first connecting via hole that penetrates through the first insulator layer and the second insulator layer, and the drain is electrically connected to a drain area of the active layer through a second connecting via hole that penetrates through the first insulator layer and the second insulator layer; and
the photoelectric sensor is in the same layer as any one of the first insulator layer, the second insulator layer and the third insulator layer; or the photoelectric sensor is located between any adjacent two of the first insulator layer, the second insulator layer and the third insulator layer.

In some examples, the first electrode layer includes a first sub-structure, a second sub-structure, and a third sub-structure connecting the first sub-structure and the second sub-structure; and
the first sub-structure, the third sub-structure and the second sub-structure are sequentially disposed in a direction pointing from the base substrate to the circuit layer.

In some examples, the first sub-structure is of an regular trapezoidal structure, the second sub-structure is of an inverted trapezoidal structure, and the third sub-structure is of a rectangular structure.

In some examples, the second sub-structure and the third sub-structure are electrically connected to the drain of the first thin-film transistor, and further, the drain of the first thin-film transistor is multiplexed as the second sub-structure and the third sub-structure; the first sub-structure is electrically connected to the third electrode layer; and further, the third electrode layer is multiplexed as the first sub-structure.

In some examples, the first electrode layer is configured as a rectangular structure.

In some examples, the photoelectric sensor is located in the bridge area, and the circuit layer includes a buffer layer, a first insulator layer and a third insulator layer which are located in the bridge area and sequentially disposed on the base substrate; and
the photoelectric sensor is in the same layer as the first insulator layer or the third insulator layer; or the photoelectric sensor is located between the first insulator layer and the third insulator layer.

In some examples, the driving circuit includes a first thin-film transistor configured to drive the photoelectric sensor; and a third connecting via hole is formed in the first insulator layer; and

The drain of the first thin-film transistor is electrically connected to the first electrode layer through the third connecting via hole, and further, the drain of the first thin-film transistor is multiplexed as the first electrode layer; or the gate of the first thin-film transistor is electrically connected to the first electrode layer through the third connecting via hole, and further, the gate of the first thin-film transistor is multiplexed as the first electrode layer.

In some examples, the via hole in the hole area is located between the island area and the bridge area; the photoelectric sensor is located on a side wall of film layers between the island area and the bridge area; and the side wall is at a preset inclination angle to the base substrate.

In some examples, the via hole in the hole area is located between the island area and the bridge area; the photoelectric sensor includes a plurality of levels of photoelectric structures; the plurality of levels of photoelectric structures is located on a side wall of film layers between the island area and the bridge area;
a first photoelectric sub-structure of an i^{th}-level photoelectric structure is connected to a second photoelectric sub-structure of an (i−1)^{th}-level photoelectric structure; a second photoelectric sub-structure of the i^{th}-level photoelectric structure is connected to a first photoelectric sub-structure of an (i+1)^{th}-level photoelectric structure; 0<i≤N, where N is a positive integer greater than or equal to 2; and
an included angle between the first photoelectric sub-structure of the i^{th}-level photoelectric structure and the second photoelectric sub-structure of the (i−1)^{th}-level photoelectric structure ranges from 85° to 105°; an included angle between the second photoelectric sub-structure of the i^{th}-level photoelectric structure and the first photoelectric sub-structure of the (i+1)^{th}-level photoelectric structure ranges from 85° to 105°; and an included angle between the first photoelectric sub-structure of the i^{th}-level photoelectric structure and the second photoelectric sub-structure of the i^{th}-level photoelectric structure ranges from 85° to 105°.

In a second aspect, an embodiment of the present disclosure further provides a method for manufacturing a display substrate, the display substrate having an island area, a hole area and a bridge area. The method for manufacturing the display substrate includes:
forming a circuit layer on a base substrate, and forming, in the circuit layer, a driving circuit located in the island area and a via hole located in the hole area; and
also forming at least one photoelectric sensor in the circuit layer, wherein the at least one photoelectric sensor is electrically connected to the driving circuit, and the photoelectric sensor includes a first electrode layer, a photoelectric structure layer and a second electrode layer which are laminated; and
the photoelectric sensor is located in the island area, and the first electrode layer, the photoelectric structure layer and the second electrode layer of the photoelectric sensor are sequentially disposed in a direction pointing from the island area to the bridge area; and/or the photoelectric sensor is located in the bridge area, and the first electrode layer, the photoelectric structure layer and the second electrode layer of the photoelectric sensor are sequentially disposed in a direction pointing from the bridge area to the island area.

In a third aspect, an embodiment of the present disclosure further provides a display apparatus. The display apparatus includes the display substrate in any example in the first aspect.

### BRIEF DESCRIPTION OF DRAWINGS

FIG. 1 is a schematic structural diagram of various areas of a display substrate as provided by an embodiment of the present disclosure;

FIG. 2 is a schematic diagram of a photoelectric sensor located in an island area as provided by an embodiment of the present disclosure;

FIG. 3 is a schematic diagram of a photoelectric sensor located in a bridge area as provided by an embodiment of the present disclosure;

FIG. 4 is a schematic structural diagram of various film layers of a display substrate when the photoelectric sensor is located in an island area as provided by an embodiment of the present disclosure;

FIG. 5 is a schematic diagram of a driving circuit of a photoelectric sensor as provided by an embodiment of the present disclosure;

FIG. 6 is a schematic diagram of a connecting structure between a drain of a first thin-film transistor and a photoelectric sensor when the photoelectric sensor is located in an island area as provided by an embodiment of the present disclosure;

FIG. 7 is a schematic diagram of a driving circuit of another photoelectric sensor as provided by an embodiment of the present disclosure;

FIG. 8 is a schematic diagram of a connecting structure between a gate of a first thin-film transistor and a photoelectric sensor when the photoelectric sensor is located in an island area as provided by an embodiment of the present disclosure;

FIG. 9 is a schematic diagram of a connecting structure between a light-emitting device and a photoelectric sensor when the photoelectric sensor is located in an island area as provided by an embodiment of the present disclosure;

FIG. 10 is a schematic structural diagram of various film layers of a display substrate when a photoelectric sensor is located in a bridge area as provided by an embodiment of the present disclosure;

FIG. 11 is a schematic diagram of a specific structure of a first electrode layer as provided by an embodiment of the present disclosure;

FIG. 12 is a schematic structure diagram of a side wall of film layers of a photoelectric sensor located between an island area and a bridge area as provided by an embodiment of the present disclosure;

FIG. 13 is a schematic structure diagram of a side wall of film layers of another photoelectric sensor located between an island area and a bridge area as provided by an embodiment of the present disclosure; and

FIGS. 14a to 14o are schematic diagrams of manufacturing flows of a display substrate as provided by an embodiment of the present disclosure.

Reference symbols represent the following components: display substrate 100; base substrate 01; circuit layer 02; photoelectric sensor 03; first electrode layer 31; first sub-structure 311; second sub-structure 312; third sub-structure 313; photoelectric structure layer 32; second electrode layer 33; first thin-film transistor T1; via hole Via0 in a hole area; buffer layer 21; first insulator layer 22; second insulator layer 23; third insulator layer 24; active layer T11 of the first thin-film transistor T1; gate T12 of the first thin-film transistor T1; source T13 of the first thin-film transistor T1; drain T14 of the first thin-film transistor T1; source area T11a of the active layer T11 of the first thin-film transistor T1; drain area T11b of the active layer T11 of the first thin-film transistor T1; first connecting via hole Via1; second connecting via hole Via2; glass sub-base 11; flexible sub-base 12; modulus material 13; light-emitting device 04; third electrode layer 41; light-emitting layer 42; fourth electrode layer 43; active layer T21 of a second thin-film transistor T2; gate T22 of the second thin-film transistor T2; source T23 of the second thin-film transistor T2; drain T24 of the second thin-film transistor T2; source area T21a of the active layer T21 of the second thin-film transistor T2; drain T21b of the active layer T21 of the first thin-film transistor T2; fourth connecting via hole Via4; fifth connecting via hole Via5; sixth connecting via hole Via6; and encapsulation film layer 05.

### DETAILED DESCRIPTION

In order to make those skilled in the art better understand the technical solutions of the present disclosure, the present disclosure will be further described below in conjunction with accompanying drawings and the specific embodiments.

The technical and scientific terms as used in the present disclosure should have the meanings as commonly understood by a person of ordinary skill in the art of the present disclosure, unless otherwise defined. The words “first”, “second” and similar terms used in the present disclosure do not denote any order, quantity, or importance, and are merely used to distinguish different components. Similarly, words such as “a”, “one” or “the” do not denote a quantitative limit, but rather the existence of at least one. The word “comprise”, “containing” or similar terms mean that elements or objects appearing before the term cover the listed elements or objects and its equivalents appearing after the term while other elements or objects are not excluded. The word “connected to” or “connected with” and similar terms are not limited to physical or mechanical connections, and may include electrical connection and the connection may be direct or indirect. “Upper”, “lower”, “left”, “right” and the like are only used to indicate the relative positional relationship, and when the absolute position of a described object changes, the relative positional relationship may also change accordingly.

It should be noted that in the present disclosure, the structures being “disposed in the same layer” means that they are formed by the same material layer and thus in the same layer in terms of a laminating relationship, but does not mean that the distances between them and a base substrate are equal, nor means that they are exactly the same as other layer structures between base substrates.

The present disclosure will be described in more detail below with reference to the accompanying drawings. In the respective drawings, the same elements are designated by similar reference numerals. For the sake of clarity, various parts in the drawings have not been drawn to scale. In addition, some well-known parts may not be shown in the drawings.

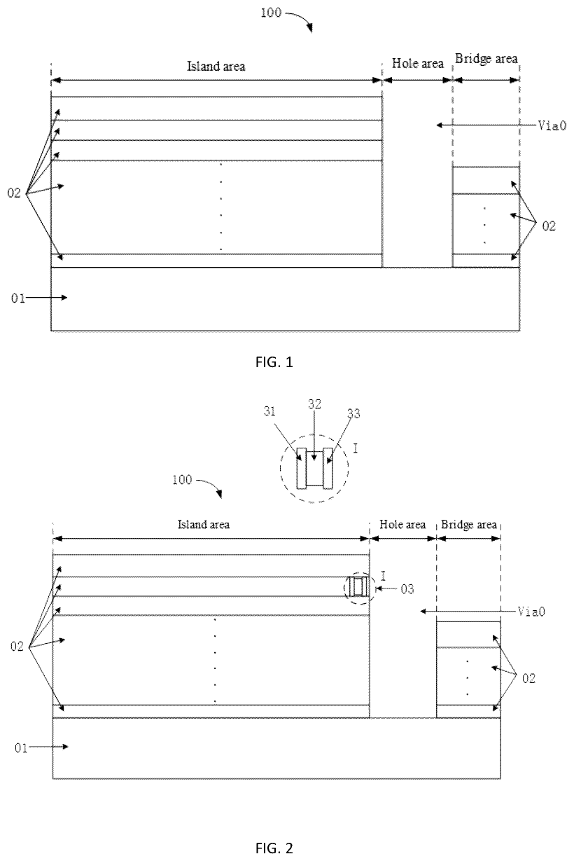

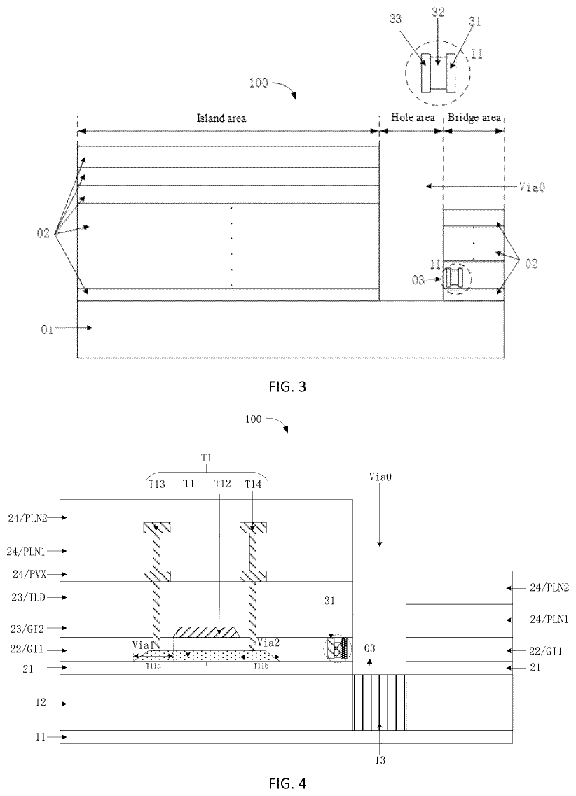

FIG. 1 is a schematic structural diagram of various areas of a display substrate as provided by an embodiment of the present disclosure; FIG. 2 is a schematic diagram of a photoelectric sensor located in an island area as provided by an embodiment of the present disclosure; and FIG. 3 is a schematic diagram of a photoelectric sensor located in a bridge area as provided by an embodiment of the present disclosure. As shown in FIG. 1, FIG. 2 and FIG. 3, the display substrate includes an island area, a hole area and a bridge area; and the display substrate 100 includes a base substrate 01, and a circuit layer 02 disposed on the base substrate 01.

The display substrate provided in this embodiment of the present disclosure is a stretchable display substrate 100. The stretchable display substrate is provided with a series of micro-hole structures, i.e., a via hole Via0 located in a hole area. The via hole Via0 divides the stretchable display substrate 100 into an island area and a bridge area. The island area is configured for image display; the via hole Via0 is configured to provide a deformation space in response to the display substrate 100 being stretched, and at the same time, also configured to transmit light; and the bridge area is configured to preform routing and transmit a tensile force. As shown in FIG. 1, a driving circuit for an organic light-emitting diode (OLED) and the photoelectric sensor is located in the island area. In response to applying an external force in a direction perpendicular to the stretchable display substrate 100, the bridge area is deformed and stretched, and meanwhile light passing through the via hole Via0 changes.

The circuit layer 02 includes a driving circuit located in the island area, and a via hole Via0 located in the hole area. The circuit layer 02 further includes at least one photoelectric sensor 03 that is electrically connected to the driving circuit; and the photoelectric sensor 03 includes a first electrode layer 31, a photoelectric structure layer 32 and a second electrode layer 33 which are laminated.

As shown in FIG. 2, the photoelectric sensor 03 is located in the island area, and the first electrode layer 31, the photoelectric structure layer 32 and the second electrode layer 33 of the photoelectric sensor 03 are sequentially disposed in a direction pointing from the island area to the bridge area.

As shown in FIG. 3, the photoelectric sensor 03 is located in the bridge area, and the first electrode layer 31, the photoelectric structure layer 32 and the second electrode layer 33 of the photoelectric sensor 03 are sequentially disposed in a direction pointing from the bridge area to the island area.

It should be noted that the via hole Via0 in the hole area is located between the island area and the bridge area, and penetrates through the circuit layer 02 in a direction perpendicular to the base substrate 01. A position of the photoelectric sensor 03 in the circuit layer 02 is close to the hole area, and the first electrode layer 31, the photoelectric structure layer 32 and the second electrode layer 33 are close to the via hole Via0 in the hole area in sequence. In an exemplary embodiment, the photoelectric sensor 03 may be an organic-photo-diode (OPD). The first electrode layer 31 functions as an anode of the photoelectric sensor 03, the second electrode layer 33 functions as a cathode of the photoelectric sensor 03, and the second electrode layer 33 is a transparent electrode layer. Light from the via hole Via0 in the hole area may be received through the second electrode layer 33.

In this embodiment of the present disclosure, the photoelectric sensor 03 is integrated into the stretchable island area and/or bridge area of the stretchable display substrate 100. The photoelectric sensor 03 can monitor a tensile status by utilizing the change of illumination after the via hole Via in the hole area changes upon being stretched, while the display substrate 100 may be used for stretchable display, electronic skin and other displays. In addition, the first electrode layer 31, the photoelectric structure layer 32 and the second electrode layer 33 of the photoelectric sensor 03 are laminated in a direction pointing from the island area to the bridge area. That is, various structures of the photoelectric sensor 03 are arranged transversely, which can not only be suitable for a stretchable backplane, but also can reduce an occupied area, and compared with the traditional OPD integration mode (OPD is generally disposed in the same layer as an organic light-emitting diode (OLED), can increase a display resolution and an opening ratio.

Under the condition that the second electrode layer 33 can receive the light from the via hole Via0 in the hole area, the photoelectric sensor 03 may be disposed at any position in the island area or the bridge area. However, in order to reduce the occupied area more fully and improve the sensitivity of an optical sensor, the photoelectric sensor 03 is disposed at the position of the circuit layer 02 close to the hole area, for example, may be embedded in the circuit layer 02, or may also be laid on the side wall of film layers located in the island area or the bridge area.

In this embodiment of the present disclosure, the photoelectric sensor 03 disposed on the display substrate 100 may be manufactured in different ways. Various structures of the display substrate 100 provided by this embodiment of the present disclosure are detailed below by taking the photoelectric sensor 03 manufactured by a solution method as an example.

In some examples, since the island area is not easily deformed and a variety of different thin-film transistors is provided, the photoelectric sensor 03 is disposed in the circuit layer 02 located in the island area in order for circuit connection. FIG. 4 is a schematic structural diagram of various film layers of a display substrate when a photoelectric sensor is located in an island area as provided by an embodiment of the present disclosure. As shown in FIG. 4, the photoelectric sensor 03 is located in the island area, and the circuit layer 02 includes a first thin-film transistor T1 located in the island area, and a buffer layer 21, a first insulator layer 22, a second insulator layer 23 and a third insulator layer 24 which are located in the island area and sequentially disposed on a base substrate 01. The first thin-film transistor T1 includes an active layer T11, a gate T12, a source T13 and a drain T14. The active layer T11 is disposed on a side of the buffer layer 21 away from the base substrate 01. The gate T12 is disposed on a side of the first insulator layer 22 away from the base substrate 01, and orthographic projections of the gate T12 and the active layer T11 on the base substrate 01 are at least partially overlapped. The source T13 and the drain T14 are disposed on a side of the second insulator layer 23 away from the base substrate 01. The source T13 is electrically connected to a source area T11a of the active layer T11 through a first connecting via hole Via1. The drain T11b is electrically connected to a drain area T11b of the active layer T11 through a second connecting via hole Via2.

The active layer of the first thin-film transistor T1 provided in this embodiment of the present disclosure may be made of a semiconductor material, such as low-temperature polysilicon or an oxide, which may be limited according to the requirements in practical applications, but not specifically limited in the embodiments of the present disclosure.

The photoelectric sensor 03 is in the same layer as any one of the first insulator layer 22, the second insulator layer 23 or the third insulator layer 24; or the photoelectric sensor 03 is located between any adjacent two of the first insulator layer 22, the second insulator layer 23 and the third insulator layer 24, e.g., located on a surface of the first insulator layer 22 away from the base substrate 01, in other words, embedded into the second insulator layer 23. FIG. 4 shows only a schematic diagram of the photoelectric sensor 03 in the same layer as the first insulator layer 22.

The base substrate 01 provided in this embodiment of the present disclosure may be a flexible substrate. The base substrate 01 may adopt a single-layer base or a multi-layer base. In the case of the multi-layer substrate, the base substrate 01 includes a glass sub-base 11 and a flexible sub-base 12 (made of a flexible material thermoplastic polyimide (PI)) which are laminated.

In one example, the via hole Via0 in the hole area penetrates through the buffer layer 21 and the flexible sub-base 12 of the base substrate 01 in addition to the circuit layer 02. In another example, as shown in FIG. 4, the via hole Via0 in the hole area penetrates through the buffer layer 21 and the flexible sub-base 12 of the base substrate 01 in addition to the circuit layer 02. The via hole of the flexible sub-base 12 is filled with a low-modulus material 13, which can improve the tensile properties of the display substrate 100.

The buffer layer 21 is usually made of an inorganic material, such as silicon oxide or silicon nitride, so as to achieve the effect of blocking water, oxygen and alkaline ions. Therefore, the buffer layer 21 has larger hardness and thickness. In response to the display substrate 100 being stretched, the buffer layer 21 is difficult to be stretched, and has a large stress, in particular resulting in cracks at the edges of the buffer layer 21 corresponding to the island area and the bridge area. In the case of a large number of cracks, the buffer layer 21 will be damaged to cause a damage to the display substrate 100. In the display substrate 100 provided by this embodiment of the present disclosure, the purpose of forming an opening in the buffer layer 21 is achieved through the via hole Via0, and the stress accumulated in response to the buffer layer 21 being stretched can be released to avoid cracks on the buffer layer 21 produced by stretching, thereby avoiding the display substrate 100 from be damaged, and improving the stretchability of the display substrate 100.

The material of the first insulator layer 22 will not be specifically limited in the embodiments of the present disclosure as long as it is a material that satisfies the insulation between the active layer T11 and the gate T12 of the first thin-film transistor T1. The first insulator layer 22 may be a first gate insulator (GI) layer GI1.

The second insulator layer 23 is configured to protect the insulation between the gate T12 of the first thin-film transistor T1 and other metallic structures (e.g., the source T13 and the drain T14 of the first thin-film transistor T1). The second insulator layer 23 may adopt a single-layer insulator layer, e.g., a second gate insulator layer GI2; or may adopt a plurality of insulating sub-layers which is laminated, e.g., a second gate insulator layer GI2 and an inter-layer dielectric (ILD) layer which are laminated. The material of the second insulator layer 23 is not specifically limited in the embodiments of the present disclosure.

The third insulator layer 24 is configured to protect the source T13 and the drain T14 of the first thin-film transistor T1. The third insulator layer 24 may adopt two insulation layers, e.g., a passivation (PVX) layer and a first plain layer PLN1 which are laminated; or may adopt more insulating sub-layers which are laminated, e.g., a passivation layer PVX, a first plain (PLN) layer PLN1 and a second plain layer PLN2 which are laminated.

It should be noted that different photoelectric sensors 03 may be in the same layer as different insulator layers, and a plurality of photoelectric sensors 03 receives light that changes in response to stretching the hole area, which can improve the detection accuracy. Different photoelectric sensors 03 may be disposed at different heights to detect the light at different positions of the via hole Via0 in the hole area.

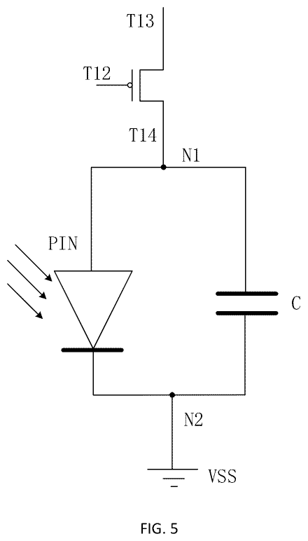

In some examples, the driving circuit includes a first thin-film transistor configured to drive the photoelectric sensor 03. FIG. 5 is a schematic diagram of a driving circuit of a photoelectric sensor as provided by an embodiment of the present disclosure. As shown in FIG. 5, the source T13 of the first thin-film transistor T1 is electrically connected to an external signal source (not shown in FIG. 5, which may be a signal source capable of providing a fixed voltage). The drain T14 of the first thin-film transistor T1 is electrically connected to the first electrode layer 31 of the photoelectric sensor 03. The photoelectric structure layer 32 of the photoelectric sensor 03 includes a photo-diode PIN and a capacitor C, wherein the photo-diode PIN and the capacitor C are connected in parallel, a first parallel terminal N1 is connected to the first electrode layer 31, and a second parallel terminal N2 is connected to the second electrode layer 33. In an exemplary embodiment, the first electrode layer 31 functions as an anode of the photoelectric sensor 03, and the second electrode layer 33 functions as a cathode of the photoelectric sensor 03 and is connected to a low supply voltage VSS.

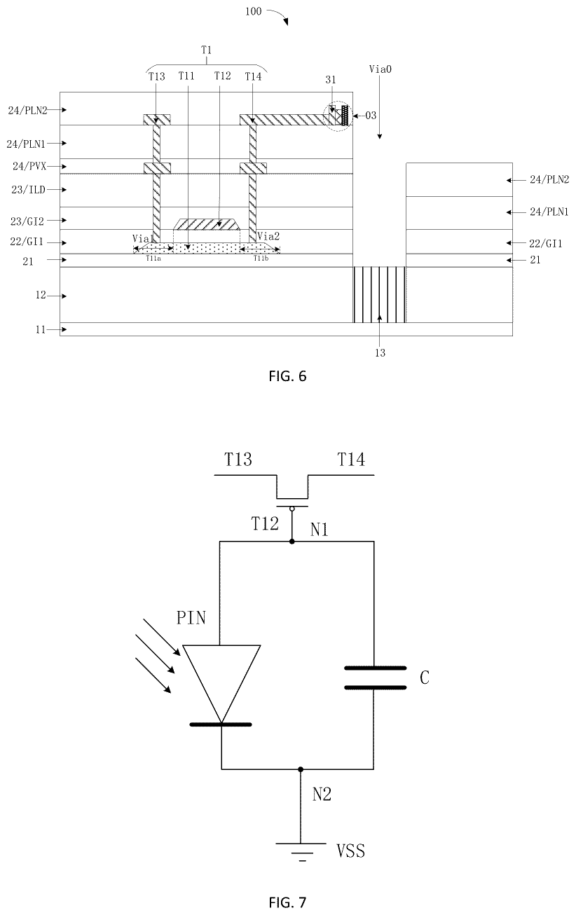

FIG. 6 is a schematic diagram of a connecting structure between a drain of a first thin-film transistor and a photoelectric sensor when the photoelectric sensor is located in an island area as provided by an embodiment of the present disclosure. As shown in FIG. 6, the drain of the first thin-film transistor is electrically connected to the first electrode layer 31 of the photoelectric sensor 03. In some embodiments, the drain of the first thin-film transistor is multiplexed as the first electrode layer 31, in other words, the drain of the first thin-film transistor is integrated with the first electrode layer 31.

In an exemplary embodiment, the drain of the first thin-film transistor is a titanium (Ti)-aluminum (Al)-titanium (Ti) metal composite layer. That is, the first electrode layer 31 is a titanium (Ti)-aluminum (Al)-titanium (Ti) metal composite layer. Of course, the material of the drain of the first thin-film transistor is not limited in the embodiments of the present disclosure. This material may be other feasible materials in addition to the titanium (Ti)-aluminum (Al)-titanium (Ti) metal composite layer, which may be specifically limited according to experience and actual scenarios, and are not enumerated in the embodiments of the present disclosure.

Here, since the drain of the first thin-film transistor may be directly multiplexed as the first electrode layer 31 of the photoelectric sensor 03, a metal electrode layer may be directly prepared in the process manufacturing stage, such that the manufacturing efficiency can be improved.

It should be noted that the photoelectric sensor 03 may be disposed in the same layer as the drain of the first thin-film transistor. As shown in FIG. 6, the photoelectric sensor 03 is disposed on a side of the first plain layer PLN1 in the third insulator layer 24 away from the base substrate 01, that is, is located in the second plain layer PLN2 in the third insulator layer 24. Of course, the photoelectric sensor 03 may also be in the same layer as other layers other than the second plain layer PLN2, that is, disposed in this layer, i.e., in the same layer as any of the first insulator layer 22, a second gate insulator layer GI2 in the second insulator layer 23, an inter-layer dielectric layer ILD in the second insulator layer 23, a passivation layer PVN in the third insulator layer 24 and the first plain layer PLN1, while other arrangements in the same layer are not enumerated in the embodiments of the present disclosure. Alternatively, the photoelectric sensor 03 may also be located between any adjacent two of the first insulator layer 22, the second gate insulator layer GI2 in the second insulator layer 23, the inter-layer dielectric layer ILD in the second insulator layer 23, the passivation layer PVX in the third insulator layer 24, the first plain layer PLN1 in the third insulator layer 24 and the second plain layer PLN2 in the third insulator layer 24, which are not enumerated in the embodiments of the present disclosure. In the case where the photoelectric sensor 03 and the drain of the first thin-film transistor are located in different layers, as shown in FIG. 4, the drain T14 of the first thin-film transistor T1 may be electrically connected to the first electrode layer 31 of the photoelectric sensor 03 through a connecting via hole.

In some examples, the driving circuit includes a first thin-film transistor configured to drive the photoelectric sensor 03. FIG. 7 is a schematic diagram of a driving circuit of another photoelectric sensor as provided by an embodiment of the present disclosure. As shown in FIG. 7, the source T13 and the drain T14 of the first thin-film transistor T1 are electrically connected to an external signal source (not shown in FIG. 7, which may be a signal source capable of providing a fixed voltage) respectively. The drain T12 of the first thin-film transistor T1 is electrically connected to the first electrode layer 31 of the photoelectric sensor 03. The photoelectric structure layer 32 of the photoelectric sensor 03 includes a photo-diode PIN and a capacitor C, wherein the photo-diode PIN and the capacitor C are connected in parallel, a first parallel terminal N1 is connected to the first electrode layer 31, and a second parallel terminal N2 is connected to the second electrode layer 33. In an exemplary embodiment, the first electrode layer 31 functions as an anode of the photoelectric sensor 03, and the second electrode layer 33 functions as a cathode of the photoelectric sensor 03 and is connected to a low supply voltage VSS.

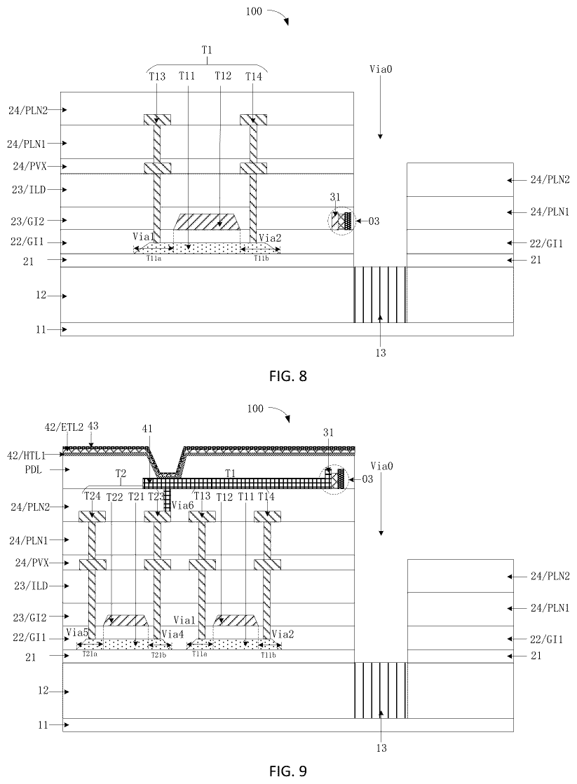

FIG. 8 is a schematic diagram of a connecting structure between a gate of a first thin-film transistor and a photoelectric sensor when the photoelectric sensor is located in an island area as provided by an embodiment of the present disclosure. As shown in FIG. 8, a gate T12 of the first thin-film transistor T1 is electrically connected to a first electrode layer 31 of the photoelectric sensor 03. In some embodiments, the gate of the first thin-film transistor is multiplexed as the first electrode layer 31. FIG. 8 is a schematic diagram of a connecting relationship between the gate T12 of the first thin-film transistor T1 and the photoelectric sensor 03, while the specific connecting structure between the gate T12 of the first thin-film transistor T1 and the first electrode layer 31 is not shown in FIG. 8.

In an exemplary embodiment, the material of the gate of the first thin-film transistor may be molybdenum (Mo) or other feasible material, which will not specifically be limited in the embodiments of the present disclosure.

Here, since the gate T12 of the first thin-film transistor T1 may be directly multiplexed as the first electrode layer 31 of the photoelectric sensor 03, a gate layer may be directly prepared in the process manufacturing stage, such that the manufacturing efficiency can be improved.

It should be noted that the photoelectric sensor 03 may be disposed in the same layer as the drain T12 of the first thin-film transistor T1. As shown in FIG. 8, the photoelectric sensor 03 is disposed on a side of the first insulator layer 22 away from the base substrate 01, that is, is disposed in the second gate insulator layer GI2 in the second insulator layer 23. Of course, the photoelectric sensor 03 may also be in the same layer as other layers other than the second gate insulator layer GI2 in the second insulator layer 23, i.e., as any one of the first insulator layer 22, the inter-layer dielectric layer ILD in the second insulator layer 23, the passivation layer PVX in the third insulator layer 24, the first plain layer PLN1 in the third insulator layer 24 and the second plain layer PLN2 in the third insulator layer 24. That is, the photoelectric sensor is disposed in this layer. However, other arrangement modes in the same layer are not enumerated in the embodiments of the present disclosure. Alternatively, the photoelectric sensor 03 may also be located between any adjacent two of the first insulator layer 22, the second gate insulator layer GI2 in the second insulator layer 23, the inter-layer dielectric layer ILD in the second insulator layer 23, the passivation layer PVX in the third insulator layer 24, the first plain layer PLN1 in the third insulator layer and the second plain layer PLN2 in the third insulator layer, which are not enumerated in the embodiments of the present disclosure. In the case where the photoelectric sensor 03 and the gate T12 of the first thin-film transistor T1 are in different layers, the gate T12 of the first thin-film transistor T1 may be electrically connected to the first electrode layer 31 of the photoelectric sensor 03 through a connecting via hole.

In some examples, FIG. 9 is a schematic diagram of a connecting structure between a light-emitting device and a photoelectric sensor when the photoelectric sensor is located in an island area as provided by an embodiment of the present disclosure. As shown in FIG. 9, a light-emitting device 04 is disposed on a side of the circuit layer 02 away from the base substrate 01. The light-emitting device 04 includes a third electrode layer 41, a fourth electrode layer 43, and a light-emitting layer 42 disposed between the third electrode layer 41 and the fourth electrode layer 43. The third electrode layer 41 is multiplexed as the first electrode layer 31, and the fourth electrode layer 43 is multiplexed as the second electrode layer 33.

The third electrode layer 41 functions as an anode AND of the light-emitting device 04, and the fourth electrode layer 43 functions as a cathode of the light-emitting device 04. The third electrode layer 41 is an indium tin oxide (ITO)-silver (Ag)-indium tin oxide (ITO) composite layer, that is, the first electrode layer 31 is an indium tin oxide (ITO)-silver (Ag)-indium tin oxide (ITO) composite layer. The material of the fourth electrode layer 43 is magnesium (Mg) or silver (Ag), that is, the material of the second electrode layer 33 is magnesium (Mg) or silver (Ag).

The light-emitting layer 42 includes a first hole transport layer HTL1 and a first exciton barrier layer ETL1.

A pixel definition layer (PDL) is disposed on the circuit layer 02 away from the base substrate 01, and a light-emitting layer 42 and a fourth electrode layer 43 are disposed on a side of the pixel definition layer PDL away from the base substrate 01.

The driving circuit further includes a second thin-film transistor T2 configured to drive a light-emitting device, wherein a source T23 of the second thin-film transistor T2 is electrically connected to a third electrode layer 41, an active layer T21 of the second thin-film transistor T2 is disposed on a side of the buffer layer 21 away from the base substrate 01, a gate T22 of the second thin-film transistor T2 is disposed on a side of the first insulator layer 22 away from the base substrate 01, and orthogonal projections of the gate T22 of the second thin-film transistor T2 and the active layer T1 of the second thin-film transistor T2 on the base substrate 01 are at least partially overlapped. The source T23 of the second thin-film transistor T2 and the drain T24 of the second thin-film transistor T2 are disposed on a side of the second insulator layer 23 away from the base substrate 01, a first terminal of the source T23 of the second thin-film transistor T2 is electrically connected to a source area T21a of the active layer T21 of the second thin-film crystal T2 through a fourth connecting via hole Via4, the drain T24 of the second thin-film transistor T2 is electrically connected to a drain area T21b of the active layer T21 of the second thin-film transistor T2 through a fifth connecting via hole Via5, and a second terminal of the source T23 of the second thin-film transistor T2 is electrically connected to the third electrode layer 41 through a sixth connecting via hole Via6.

Here, since the third electrode layer 41 may be directly multiplexed as the first electrode layer 31 of the photoelectric sensor 03, and the fourth electrode layer 41 may be directly multiplexed as the second electrode layer 33 of the photoelectric sensor 03, the electrode layers which are multiplexed each other may be directly prepared into one layer in the process manufacturing stage, such that the manufacturing efficiency can be improved. Of course, the first electrode layer 31 and the second electrode layer 33 may also be prepared separately, and the third electrode layer 41 and the fourth electrode layer 43 of the light-emitting device are not multiplexed.

It should be noted that, as shown in FIG. 9, the photoelectric sensor 03 and the pixel definition layer PDL may be disposed in the same layer, that is, the photoelectric sensor 03 is disposed on a side of the third insulator layer 24 away from the base substrate 01. Compared with the layered arrangement in which the connecting via holes need to be formed, the arrangement in the same layer can improve the preparation efficiency and save the material cost. Of course, the photoelectric sensor 03 may also be in the same layer as different insulator layers, which will not be specifically limited in the embodiments of the present disclosure.

It should be noted that the materials of the active layer, the source, the drain and the gate of the second thin-film transistor may refer to the description of specific materials of various structures of the first thin-film transistor, and the repeated parts will not be described again.

In some examples, the first electrode layer 31 is configured as a rectangular structure, which can enhance a signal, prevent light of the signal from being dispersed up and down, and increase a signal-to-noise ratio.

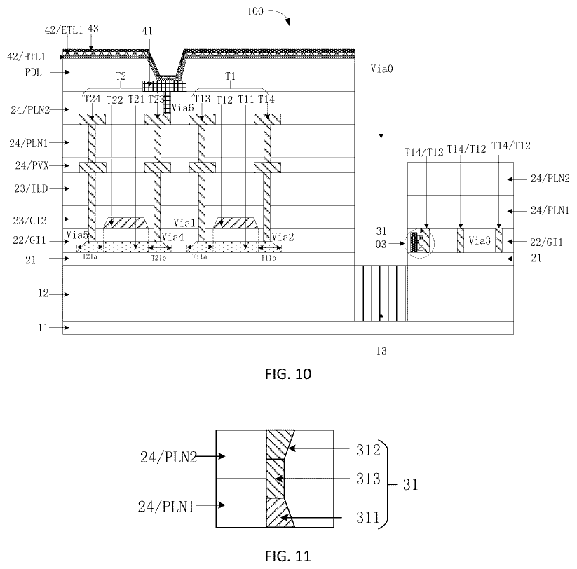

In some examples, since the wiring in the bridge area is mostly drive lines of the source and drain, less gate drive lines are provided. In addition, the photoelectric sensor 03 may be disposed in the circuit layer 02 located in the bridge area due to small noise in OPD wiring, flexibility of OPD material and resistance to the deformation of the bridge area. Taking the driving circuit shown in FIG. 5 as an example, FIG. 10 is a schematic structural diagram of various film layers of a display substrate when a photoelectric sensor is located in a bridge area as provided by an embodiment of the present disclosure. As shown in FIG. 10, the photoelectric sensor 03 is located in the bridge area, and the circuit layer 02 includes a buffer layer 21, a first insulator layer 22 and a third insulator layer 24 which are located in the bridge area and sequentially disposed on the base substrate 01.

The photoelectric sensor 03 is in the same layer as the first insulator layer 22 or the third insulator layer 24; or the photoelectric sensor 03 is located between the first insulator layer 22 and the third insulator layer 24, that is, located on a surface of the first insulator layer 22 away from the base substrate 01. FIG. 10 shows a schematic diagram of the photoelectric sensor 03 in the same layer as the first insulator layer 22.

Here, the material of the buffer layer 21 is the same as that of the buffer layer 21 in the example shown in FIG. 4, both of which have the same function; the material of the first insulator layer 22 is the same as that of the first insulator layer 21 in the example shown in FIG. 4, both of which have the same function; the material of the third insulator layer 22 is the same as that of the third insulator layer 24 in the example shown in FIG. 4, both of which have the same function; and repeated parts are not described again.

In some examples, at least one third connecting via hole Via3 is formed in the first insulator layer 22 of the bridge area. As shown in FIG. 10, if the drain T14 of the first thin-film transistor T1 is disposed at the third connecting via hole Via3, the drain T14 of the first thin-film transistor T1 is in the same layer as the first insulator layer 22 located in the bridge area, and the first electrode layer 31 of the photoelectric sensor 03 is electrically connected to the drain T14 of the first thin-film transistor T1. In some embodiments, the drain T14 of the first thin-film transistor T1 is multiplexed as the first electrode layer 31 of the photoelectric sensor 03.

If the gate of the first thin-film transistor is disposed at the third connecting via hole, the gate of the first thin-film transistor is in the same layer as the first insulator layer 22 located in the bridge area, and the first electrode layer 31 of the photoelectric sensor 03 is electrically connected to the drain T12 of the first thin-film transistor T1. In some embodiments, the gate T12 of the first thin-film transistor T1 is multiplexed as the first electrode layer 31 of the photoelectric sensor 03.

In some examples, FIG. 11 is a schematic diagram of a specific structure of a first electrode layer as provided by an embodiment of the present disclosure. As shown in FIG. 11, taking a preferred arrangement in which the photoelectric sensor 03 and the third insulator layer 24 are located in the same layer and disposed between the first plain layer PLN1 and the second plain layer PLN2 as an example, the third insulator layer 24 here may be the third insulator layer 24 located in the island area, or the third insulator layer 24 located in the bridge area. The first electrode layer 31 includes a first sub-structure 311, a second sub-structure 312 and a third sub-structure 313 connecting the first sub-structure 311 and the second sub-structure 312; and the first sub-structure 311, the third sub-structure 313 and the second sub-structure 312 are sequentially disposed in a direction pointing from the base substrate 01 to the circuit layer 02.

The first sub-structure 311 and the second sub-structure 312 are of a trapezoidal structure respectively, wherein the first sub-structure 311 is shaped as an obverse right-angled trapezoid, the second sub-structure 312 is shaped as an inverted right-angled trapezoid, and the third sub-structure 313 is of a rectangular structure, which can enhance a signal, prevent light of the signal from being dispersed up and down, and increase a signal-to-noise ratio. Specifically, the first sub-structure 311 and the second sub-structure 312 of the trapezoid shown in FIG. 11 may be deposited by exposing and etching the first plain layer PLN1 and the second plain layer PLN2 into a trapezoid structure. As shown in FIG. 11, the right-angled sides of the first sub-structure 311 and the second sub-structure 312 and a long side of the third sub-structure 313 are disposed on the same side to form a plane, so that the hypotenuses of the first sub-structure 311 and the second sub-structure 312 and the other long side of the third sub-structure 313 are disposed on the same side, and thus one side of the formed first electrode layer 31 is concave.

Example 1: the second sub-structure 312 and the third sub-structure 313 are electrically connected to the drain T14 of the first thin-film transistor T1, and the drain T14 of the first thin-film transistor T1 is multiplexed as the second sub-structure 312 and the third sub-structure 313. The first sub-structure 311 is electrically connected to the third electrode layer 41, and the third electrode layer 41 is multiplexed as the first sub-structure 311. Example 2: the first sub-structure 311, the second sub-structure 312 and the third sub-structure 313 are electrically connected to the third electrode layer 41, and the third electrode layer 41 is multiplexed as the first sub-structure 311, the second sub-structure 312 and the third sub-structure 313 at the same time. Example 3: the drain T14 of the first thin-film transistor T1 is multiplexed as the first sub-structure 311, the second sub-structure 312 and the third sub-structure 313 at the same time.

In this embodiment of the present disclosure, in addition to various structures of the display substrate 100 of the photoelectric sensor 03 which is manufactured by a solution method, various structures of the display substrate 100 provided by this embodiment of the present disclosure are detailed below by taking the photoelectric sensor 03 manufactured by an evaporation method as an example.

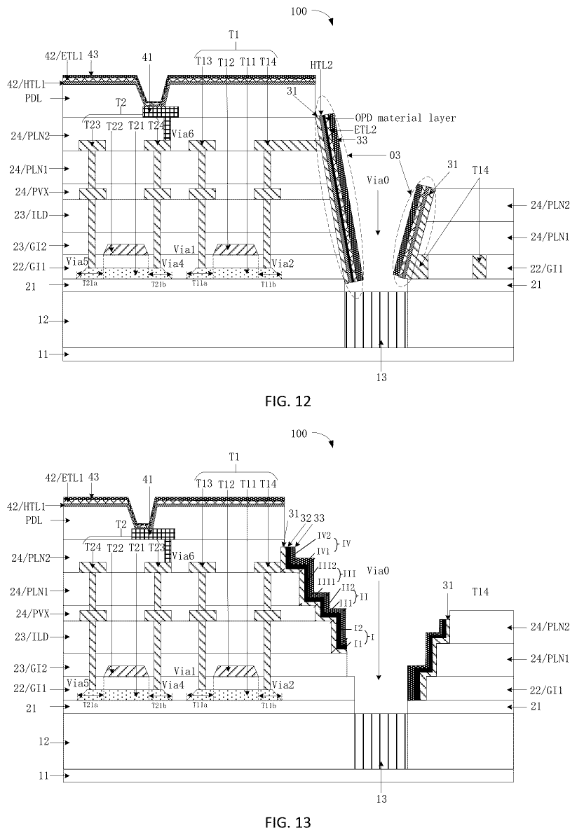

In some examples, FIG. 12 is a schematic structure diagram of a side wall of film layers of a photoelectric sensor located between an island area and a bridge area as provided by an embodiment of the present disclosure. As shown in FIG. 12, the via hole Via0 in the hole area is located between the island area and the bridge area; the photoelectric sensor 03 is located on a side wall of film layers between the island area and the bridge area; and the side wall is at a preset inclination angle to the base substrate 01.

Here, the preset inclination angle may be set empirically, which is not specifically limited in the embodiments of the present disclosure.

It should be noted that the side walls of the respective side walls between the island area and the bridge area include side walls of the respective film layers located in the island area and side walls of the respective film layers located in the bridge area.

The first electrode layer 31, the photoelectric structure layer 32 and the second electrode layer 33 are sequentially laminated on the side wall of film layers located in the island area in a direction pointing from the island area to the bridge area; and/or the first electrode layer 31, the photoelectric structure layer 32 and the second electrode layer 33 are sequentially laminated on the side wall of film layers located in the bridge area in a direction pointing from the bridge area to the island area.

In this embodiment of the present disclosure, the drain T14 of the first thin-film transistor T1 may be multiplexed as the first electrode layer 31; or the gate T12 of the first thin-film transistor T1 may be multiplexed as the first electrode layer 31; or the third electrode layer 41 may be multiplexed as the first electrode layer 31. The specific structure connecting example may refer to various structures of the display substrate 100 corresponding to the photoelectric sensor manufactured by the solution method, and the repeated parts are not described again.

As shown in FIG. 12, taking the driving circuit shown in FIG. 5 as an example, the drain T14 of the first thin-film transistor T1 is electrically connected to the first electrode layer 31, and the drain T14 of the first thin-film transistor T1 is multiplexed as the first electrode layer 31.

In some examples, FIG. 13 is a schematic structure diagram of a side wall of film layers of another photoelectric sensor located between an island area and a bridge area as provided by an embodiment of the present disclosure. As shown in FIG. 13, the via hole in the hole area is located between the island area and the bridge area. The photoelectric sensor 03 includes a plurality of levels of photoelectric structures, and the plurality of levels of photoelectric structures is located on the side wall of film layers between the island area and the bridge area. A first photoelectric sub-structure of an i^{th}-level photoelectric structure is connected to a second photoelectric sub-structure of an (i−1)^{th}-level photoelectric structure; a second photoelectric sub-structure of the i^{th}-level photoelectric structure is connected to a first photoelectric sub-structure of an (i+1)^{th}-level photoelectric structure; and 0<i≤N, where N is a positive integer greater than or equal to 2. For example, as shown in FIG. 13, the photoelectric sensor 03 located on the side wall of the island area includes four levels of photoelectric structures I-IV, wherein the I-level photoelectric structure includes a first photoelectric sub-structure I1 and a second photoelectric structure I2, the II-level photoelectric structure includes a first photoelectric sub-structure II1 and a second photoelectric structure II2, the III-level photoelectric structure includes a first photoelectric sub-structure III1 and a second photoelectric structure III2, and the IV-level photoelectric structure includes a first photoelectric sub-structure IV1. The first photoelectric sub-structure II1 of the II-level photoelectric structure is connected to the second photoelectric sub-structure I2 of the I-level photoelectric structure; and the second photoelectric sub-structure II2 of the II-level photoelectric structure is connected to the first photoelectric sub-structure III1 of the III-level photoelectric structure. An included angle between the first photoelectric sub-structure of the i^{th}-level photoelectric structure and the second photoelectric sub-structure of the (i−1)^{th}-level photoelectric structure ranges from 85° to 105°; an included angle between the second photoelectric sub-structure of the i^{th}-level photoelectric structure and the first photoelectric sub-structure of the (i+1)^{th}-level photoelectric structure ranges from 85° to 105°; and an included angle between the first photoelectric sub-structure of the i^{th}-level photoelectric structure and the second photoelectric sub-structure of the i^{th}-level photoelectric structure ranges from 85° to 105°.

In an exemplary embodiment, in order for manufacturing, the included angle between a first photoelectric sub-structure and a second photoelectric sub-structure which are connected may be set to 90°. Of course, those skilled in the art should know that a corner formed between a first photoelectric sub-structure and a second photoelectric sub-structure which are connected may be within an allowable error range of a 90° corner.

The plurality of levels of photoelectric structures forms a ladder-shaped photoelectric structure, and the side wall of film layers between the island area and the bridge area is also configured as a ladder-shaped structure to adapt to the ladder-shaped plurality of levels of photoelectric structures.

In this embodiment of the present disclosure, the side wall of film layers located between the island area and the bridge area has a large slope or ladder shape, which can increase a surface area of the photoelectric sensor 03, increase the signal intensity, and then increase a display resolution and an opening rate, without occupying the area of the circuit layer 02.

In some examples, a light-emitting layer is disposed on a side of the circuit layer 02 away from the base substrate 01; and the light-emitting layer includes a first hole transport layer HTL1 and a first exciton barrier layer ETL1. The photoelectric structure layer 32 includes a second hole transport layer HTL2, a second exciton barrier layer ETL2 and a photoelectric material layer (i.e., an OPD material layer) that are sequentially laminated in a direction pointing from the first electrode layer 31 to the second electrode layer 33. The first hole transport layer HTL1 is connected to the second hole transport layer HTL2, and the first hole transport layer HTL1 is multiplexed as the second hole transport layer HTL2. The first exciton barrier layer ETL1 is connected to the second exciton barrier layer ETL2, and the first exciton barrier layer ETL1 is multiplexed as the second exciton barrier layer ETL2.

The first hole transport layer HTL1 and the first exciton barrier layer ETL1 in the light-emitting layer are sequentially laminated in a direction pointing from the third electrode layer to the fourth electrode layer.

As shown in FIG. 12, the second hole transport layer HTL2, the second exciton barrier layer ETL2 and the photoelectric material layer in the photoelectric structure layer 32 together form a photo-diode PIN and a capacitor C.

Here, the first hole transport layer HTL1 is multiplexed as the second hole transport layer HTL2, and the first exciton barrier layer ETL1 is multiplexed as the second exciton barrier layer ETL2, which can save the cost of devices and materials.

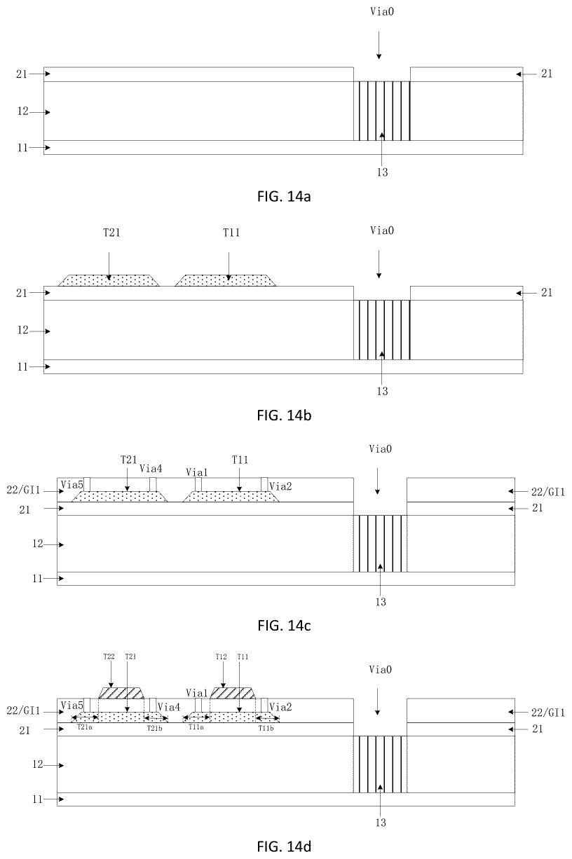

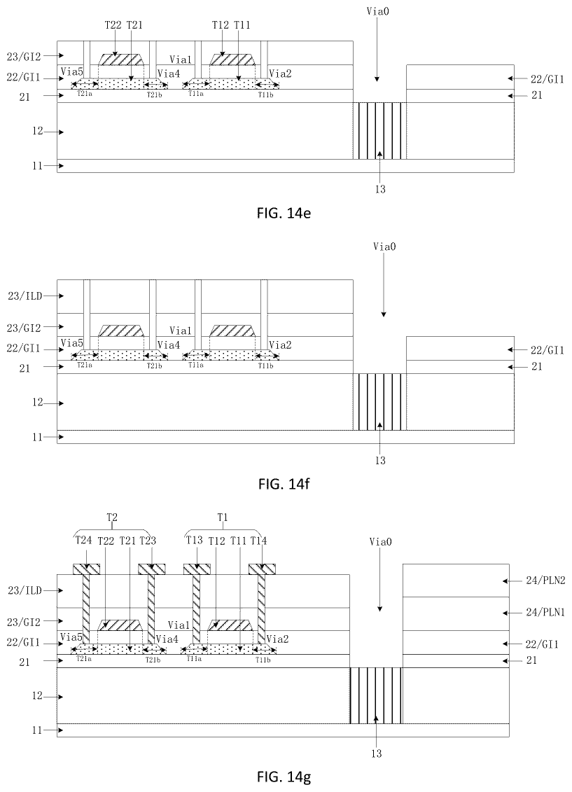

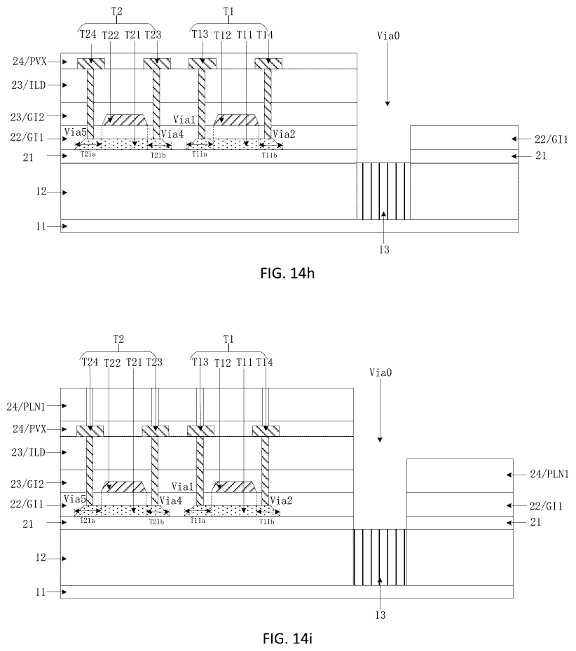

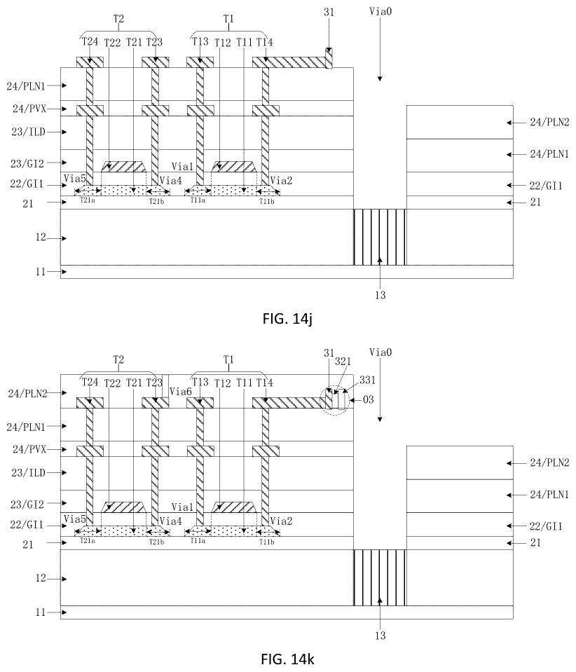

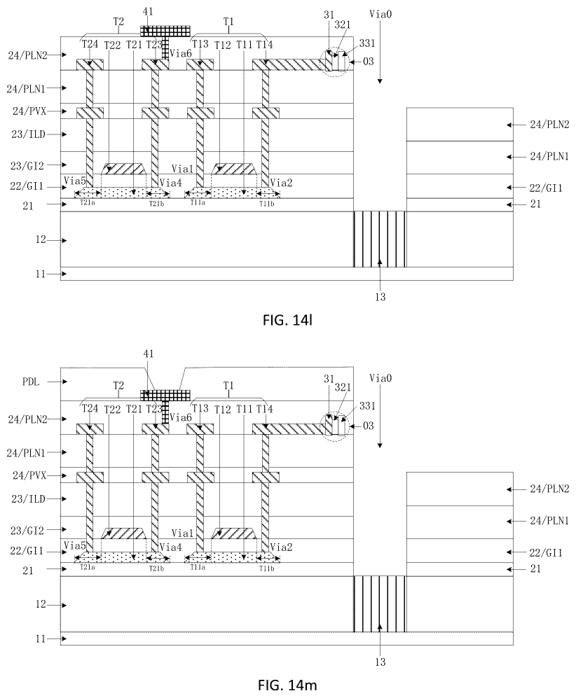

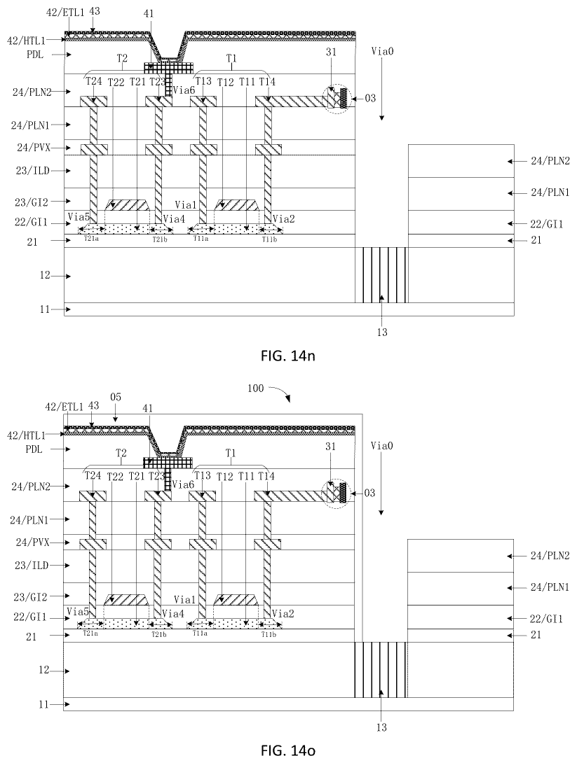

In some examples, an encapsulation film layer 05 is disposed on the outer side of the display substrate 100, that is, the outer wall of film layers located in the island area and the bridge area. The encapsulation film layer 05 is, for example, a film layer of PTFE TFE material. FIG. 14o only shows the encapsulation film layer 05 disposed on the outside of the island area.

Based on the same inventive concept, an embodiment of the present disclosure further provides a method for manufacturing a display substrate 100. Since the principle of solving the problems by the method for manufacturing the display substrate 100 in the embodiment of the present disclosure is similar to that of the display substrate 100 in the above embodiment of the present disclosure, various structures of the display substrate 100 in the method for manufacturing the display substrate 100 may refer to the display substrate 100 provided in the above embodiment, and the repeated parts will not be described again.

An embodiment of the present disclosure provides a method for manufacturing a display substrate 100. The display substrate 100 has an island area, a hole area and a bridge area. The method for manufacturing the display substrate 100 includes: forming a circuit layer 02 on a base substrate 01; forming, in the circuit layer 02, a driving circuit located in the island area, and a via hole located in the hole area; forming at least one photoelectric sensor 03 that is electrically connected to the driving circuit in the circuit layer 02, wherein the photoelectric sensor 03 includes a first electrode layer 31, a photoelectric structure layer 32 and a second electrode layer 33 which are laminated; the photoelectric sensor 03 is located in the island area, and the first electrode layer 31, the photoelectric structure layer 32 and the second electrode layer 33 of the photoelectric sensor 03 are sequentially disposed in a direction pointing from the island area to the bridge area; and/or the photoelectric sensor 03 is located in the bridge area, and the first electrode layer 31, the photoelectric structure layer 32 and the second electrode layer 33 of the photoelectric sensor 03 are sequentially disposed in a direction pointing from the bridge area to the island area.

In this embodiment of the present disclosure, the photoelectric sensor 03 is integrated into the display substrate 100 located in the stretchable island area and/or bridge area, and the display substrate 100 is stretched. The photoelectric sensor 03 can monitor a tensile status by utilizing the change of illumination after the via hole Via0 in the hole area changes upon being stretched, while the display substrate may be used for stretchable display, electronic skin and other displays. In addition, the first electrode layer 31, the photoelectric structure layer 32 and the second electrode layer 33 in the photoelectric sensor 03 are laminated in a direction pointing from the island area to the bridge area. That is, various structures of the photoelectric sensor 03 are arranged transversely, which can reduce an occupied area, and increase a display resolution and an opening ratio.

In some examples, the photoelectric sensor 03 is manufactured by using a solution method. In order to further clearly describe the preparation of film layers, taking the driving circuit in FIG. 5 as an example, the following steps S1 to S15 are elaborated in detail. FIGS. 14a to 14o are schematic diagrams of a manufacturing flow of a display substrate as provided by an embodiment of the present disclosure.

In S1, a buffer layer 21 is formed on the base substrate 01, and a buffer layer 21 located in a hole area is etched to form a via hole Via that penetrates through the buffer layer 21, as shown in FIG. 14a.

In some examples, the base substrate 01 includes a glass sub-base 11 and a flexible sub-base 12, a via hole that penetrates through the flexible sub-base 12 is formed in an area where an orthographic projection of the hole area on the base substrate 01 is located, and the via hole that penetrates through the flexible sub-base is filled with a low-modulus material 13.

The buffer layer 21 may be deposited by means of chemical vapor deposition (CVD) or atomic layer deposition (ALD).

It should be noted that the buffer layers 21 located in the island area and the bridge area are manufactured on the base substrate 01 at the same time.

In S2, an active layer T11 of a first thin-film transistor T1 and an active layer T21 of a second thin-film transistor T2 are formed on a side of the buffer layer 21 away from the base substrate 01, as shown in FIG. 14b.

Specifically, firstly, a semiconductor layer is deposited on the base substrate 01; and then, the active layer T11 of the first thin-film transistor T1 and the active layer T21 of the second thin-film transistor T2 are obtained by coating photoresist on a side of the semiconductor layer away from the base substrate 01, followed by exposure, development, etching, peeling and other processes. The semiconductor layer may be deposited on the base substrate 01 by means of CVD or ALD.

In S3, a first insulator layer 22 (i.e., a first gate insulator layer) is formed on a side of the active layer T11 of the first thin-film transistor T11 away from the base substrate 01, and a first connecting via hole Via1 and a second connecting via hole Via2 which penetrate through the first insulator layer 22 are formed in an area where orthogonal projections of a source area T11a and a drain area T11b of the active layer T11 of the first thin-film transistor T11 are located; and a fourth connecting via hole Via4 and a fifth connecting via hole Via5 that penetrate through the first insulator layer 22 are formed in an area where orthogonal projections of a source area T21a and a drain area T21b of an active layer T21 of the second thin-film transistor T2 are located, as shown in FIG. 14c.

The first insulator layer 22 may be a first gate insulator layer GI1, which is configured to protect the active layer T11 of the first thin-film transistor T1.

Since the resulting display substrate has a plurality of insulator layers, which has a great depth, so it is difficult to perform a punching process throughout the plurality of insulator layers at one time. Therefore, a mode of punching in batches through the same connecting via hole is adopted in the embodiments of the present disclosure. In one case, in order to reduce the difficulty of punching process, in the event of each deposition of an insulator layer, a connecting sub via hole that is connected to the via hole is formed throughout this insulator layer. For example, after a first gate insulator layer GI1 is deposited, a first connecting via hole Via1 and a second connecting via hole Via2 which penetrate through the first insulator layer 22 are formed in an area where orthogonal projections of a source area T11a and a drain area T11b of the active layer T11 of the first thin-film transistor T11 are located, and so on. After another gate insulator layer is deposited, a first connecting via hole Via1 and a second connecting via hole Via2 which penetrate through the first insulator layer 22 are formed in an area where orthogonal projections of a source area T11a and a drain area T11b of the active layer T11 of the first thin-film transistor T11 are located. In another case, for the connecting via holes that penetrate through the plurality of insulator layers, in order to reduce the difficulty of the punching process, the number of punching is reduced, while the manufacturing efficiency of the display substrate 100 is improved. After two or more insulator layers have been deposited, the punching preparation process is performed. The specific punching preparation process may refer to the punching process performed by each deposition of an insulator layer.

It should be noted that the first insulator layers 22 located in the island area and the bridge area are manufactured on the base substrate 01 at the same time.

In S4, a gate T12 of the first thin-film transistor T1 and a gate T22 of the second thin-film transistor T2 are formed on a side of the first insulator layer 22 away from the base substrate 01, and orthogonal projections of the gate T12 of the first thin-film transistor T1 and the active layer T11 of the first thin-film transistor T1 on the base substrate 01 are overlapped; and the orthogonal projections of the gate T22 of the second thin-film transistor T2 and the active layer T21 of the second thin-film transistor T2 on the base substrate 01 are overlapped, as shown in FIG. 14d.

The implementation of the gate of the first thin-film transistor T1 deposited in this step may refer to the implementation of the active layer T11 of the first thin-film transistor T1 deposited in S2, and the specific preparation principle will not be repeated.

In S5, a second insulator layer GI2 is formed on a side of the gate T12 of the first thin-film transistor T1 away from the base substrate 01, and a first connecting via hole Via1 and a second connecting via hole Via2 which penetrate through the second insulator layer GI2 are formed in an area where orthogonal projections of a source area T11a and a drain area T11b of the active layer T11 of the first thin-film transistor T11 are located; and a fourth connecting via hole Via4 and a fifth connecting via hole Via5 that penetrate the second insulator layer GI2 are formed in an area where orthogonal projections of a source area T21a and a drain area T21b of an active layer T21 of the second thin-film transistor T2 are located, as shown in FIG. 14e.

The second gate insulator layer GI2 is configured to protect the gate T12 of the first thin-film transistor T1 and the gate T22 of the second thin-film transistor T2.

In S6, an inter-layer dielectric layer ILD is formed on a side of the second gate insulator layer GI2 away from the base substrate 01, and a first connecting via hole Via1 and a second connecting via hole Via2 which penetrate through the inter-layer dielectric layer ILD are formed in an area where orthogonal projections of the source area T11a and the drain area T11b of the active layer T11 of the first thin-film transistor T11 are located; and a fourth connecting via hole Via4 and a fifth connecting via hole Via5 that penetrate through the inter-layer dielectric layer ILD are formed in an area where orthogonal projections of the source area T21a and the drain area T21b of the active layer T21 of the second thin-film transistor T2 are located, as shown in FIG. 14f.

In S7, a source T13 and a drain T14 of the first thin-film transistor T1, and a source T23 and a drain T24 of the second thin-film transistor T2 are formed on a side of the inter-layer dielectric layer ILD away from the base substrate 01, wherein the source T13 of the first thin-film transistor T1 is electrically connected to the source area T11a of the first thin-film transistor T1 through the first connecting via hole Via1, and the drain T14 of the first thin-film transistor T1 is electrically connected to a drain area T11b of the first thin-film transistor T1 through the second connecting via hole Via2; and the source T23 of the second thin-film transistor T2 is electrically connected to a source area T21a of the second thin-film transistor T2 through the fourth connecting via hole Via4, and the drain T24 of the second thin-film transistor T2 is electrically connected to the drain area T21b of the second thin-film transistor T2 through a fifth connecting via hole Via5, as shown in FIG. 14g.

The implementation of the source T13 and the drain T14 of the first thin-film transistor T1 deposited in this step may refer to the implementation of the active layer T11 of the first thin-film transistor T1 deposited in S2, and the specific preparation principle will not be repeated.

In S8, a passivation layer PVX is formed on a side of the inter-layer dielectric layer ILD, the source T13 and drain T14 of the first thin-film transistor T1, and the source T23 and drain T24 of the second thin-film transistor T2 away from the base substrate 01 respectively, as shown in FIG. 14h.

The passivation layer PVX covers the source T13 and drain T14 of the first thin-film transistor T1 and the source T23 and drain T24 of the second thin-film transistor T2, and is configured to protect the source T13 and drain T14 of the first thin-film transistor T1 and the source T23 and drain T24 of the second thin-film transistor T2.

In S9, a first plain layer PLN1 is formed on a side of the passivation layer PVX away from the base substrate 01, and a first connecting via hole Via1 and a second connecting via hole Via2 which penetrate through the first plain layer PLN1 are formed in an area where orthogonal projections of the source T13 and the drain T14 of the first thin-film transistor T11 are located; and a fourth connecting via hole Via4 and a fifth connecting via hole Via5 that penetrate the first plain layer PLN1 are formed in an area where orthogonal projections of the source T23 and the drain T24 of the second thin-film transistor T2 are located, as shown in FIG. 14i.

It should be noted that the first plain layers PLN1 located in the island area and the bridge area are prepared on the base substrate 01 at the same time. In the bridge area, the first plain layer PLN1 is formed on a side of the first gate insulator layer GI1 away from the base substrate 01.

In S10, a source T13 and a drain T14 of the first thin-film transistor T1, and a source T23 and a drain T24 of the second thin-film transistor T2 are formed on a side of the first plain layer PLN1 away from the base substrate 01, wherein the source T13 of the first thin-film transistor T1 is electrically connected to the source T13 of the first thin-film transistor T1 located at the passivation layer PVX through the first connecting via hole Via1, and the drain T14 of the first thin-film transistor T1 is electrically connected to the drain T14 of the first thin-film transistor T1 located at the passivation layer PVX through the second connecting via hole Via2; and the source T23 of the second thin-film transistor T2 is electrically connected to the source T23 of the second thin-film transistor T2 located at the passivation layer PVX through the fourth connecting via hole Via4, and the drain T24 of the second thin-film transistor T2 is electrically connected to the drain T24 of the second thin-film transistor T2 located at the passivation layer PVX through the fifth connecting via hole Via5. In addition, the drain T14 of the first thin-film transistor T1 is multiplexed as the first electrode layer 31 of the photoelectric sensor 03.

In this case, the photoelectric sensor 03 is located on a side of the first plain layer PLN1 away from the base substrate 01, that is, in the same layer as the second plain layer PLN2, as shown in FIG. 14j.

In S11, a second plain layer PLN2 is formed on a side of the source T13 and drain T14 of the first thin-film transistor T1 prepared in S10 away from the base substrate 01; and after exposure, etching and graphic typesetting on the second plain layer PLN2, a via hole 321 in the photoelectric structure layer 32 and a via hole 331 in the second electrode layer 33 to be coated on the photoelectric sensor 03 are reserved, as shown in FIG. 14k.

The photoelectric structure layer 32 of the photoelectric sensor 03 is coated in the reserved via holes, while the light-emitting device is manufactured in S14. The photoelectric structure layer 32 includes a second hole transport layer HTL2, a photoelectric material layer (OPD material) and a second exciton barrier layer ETL2, wherein the second exciton barrier layer may also be made of an ink material and may be printed directly with ink; then, a pattern is formed by coating with a photoresist tape and etching with oxygen; and finally, ITO or Mg or Ag material is deposited as the second electrode layer 33.

It should be noted that a second plain layers PLN2 located in the island area and the bridge area are prepared on the base substrate 01 at the same time, and the photoelectric sensor 03 may be manufactured in the island area and the bridge area at the same time, respectively.

In S12, a sixth connecting via hole Via6 that penetrates through the second plain layer PLN2 is formed in an area where an orthographic projection of the second thin-film transistor T2 manufactured in S10 is located, and a third electrode layer 41 of the light-emitting device is formed on a side of the second plain layer PLN2 away from the base substrate 01; and the third electrode layer 41 is electrically connected to the source T23 of the second thin-film transistor T2 through the sixth connecting via hole Via6, as shown in FIG. 14l.

In S13, a pixel definition layer PDL is formed on a side of the second plain layer PLN2 away from the base substrate 01, and a groove is formed in a set position. For example, a via hole is formed in a position of the pixel definition layer PDL corresponding to the third electrode layer 41 to expose the third electrode layer 41, as shown in FIG. 14m.

It should be noted that only the pixel definition layer PDL is formed on a side of the second plain layer PLN2 located in the island area away from the base substrate 01.

In S14, a light-emitting layer 42 and a fourth electrode layer 43 of the light-emitting device are sequentially formed on a side of the pixel definition layer PDL away from the base substrate 01, as shown in FIG. 14n.

The light-emitting device 04 includes a third electrode layer 41, a fourth electrode layer 43 and a light-emitting layer 42. The third electrode layer 41 functions as an anode, and the fourth electrode layer 43 functions as a cathode. The light-emitting layer 42 includes a first hole transport layer HTL1 and a first exciton barrier layer ETL1. The first hole transport layer HTL1, the first exciton barrier layer ETL1 and the fourth electrode layer 43 are sequentially deposited on a side of the pixel definition layer PDL away from the base substrate 01. The first hole transport layer HTL1 is multiplexed as the second hole transport layer HTL2 of the photoelectric sensor 03, and the first exciton barrier layer ETL1 is multiplexed as the second exciton barrier layer ETL2 of the photoelectric sensor 03. The specific multiplexed connecting structure is not shown in FIG. 14n.

It should be noted that when the first hole transport layer HTL1, the first exciton barrier layer ETL1 and the fourth electrode layer 43 are prepared, the photoelectric structure layer 32 and the second electrode layer 33 of the photoelectric sensor 03 are simultaneously coated, and the specific preparation process is described in S11.

In S15, an encapsulation film layer 05 is formed on the outer wall of film layers located in the island area and the bridge area, as shown in FIG. 14o. FIG. 14o only shows the encapsulation film layer 05 in the island area.

In some examples, as shown in FIG. 12, the photoelectric sensor 03 is manufactured by using an evaporation method. In order to further clearly describe the preparation of film layers, taking the driving circuit in FIG. 5 as an example, the photoelectric sensor 03 is obtained by evaporation on the side wall of film layers between the island area and the bridge area, after the first thin-film transistor T1, the second thin-film transistor T2 and the light-emitting device 04 are manufactured according to the preparation process in steps S1 to S14. The photoelectric sensor 03 located in the island area includes a first electrode layer 31, a second hole transport layer HTL2 (e.g., HTL material), a photoelectric material layer (e.g., OPD light-emitting material), a second exciton barrier layer ETL2 (e.g., ETL material) and a second electrode layer 33 that are sequentially laminated along a direction pointing from the island area to the bridge area. The photoelectric sensor 03 located in the bridge area includes a first electrode layer 31, a second hole transport layer HTL2, a photoelectric material layer, a second exciton barrier layer ETL2 and a second electrode layer 33 that are sequentially laminated along a direction pointing from the bridge area to the island area.

The drain T14 of the first thin-film transistor T1 is multiplexed as the first electrode layer 31 (anode) of the photoelectric sensor 03, and the first hole transport layer HTL1 of the light-emitting device 04 is multiplexed as the first hole transport layer HTL1 of the photoelectric sensor 03. A photoelectric material layer is deposited on a side of the first hole transport layer HTL1 near the via hole in the hole area. The first exciton barrier layer ETL1 of the light-emitting device 04 is multiplexed as the second exciton barrier layer ETL2 of the photoelectric sensor 03, and the fourth electrode layer 43 of the light-emitting device 04 is multiplexed as the second electrode layer 33 of the photoelectric sensor 03.

If the side wall of film layers located between the island area and the bridge area is at a preset inclination angle to the base substrate 01, the photoelectric sensor 03 formed by evaporation is in the shape of a large slope. If the side wall of film layers between the island area and the bridge area is ladder-shaped, the photoelectric sensor 03 formed by evaporation is ladder-shaped. Specifically, it may refer to an embodiment in which the photoelectric sensor 03 in the above embodiment is of a ladder-shaped structure, as shown in FIG. 13.

Based on the same inventive concept, an embodiment of the present disclosure further provides a display apparatus. The display apparatus includes the display substrate 100 in the above embodiment. Since the principle of solving the problems by the display apparatus in the embodiment of the present disclosure is similar to that of the display substrate 100 in the above embodiment of the present disclosure, various structures of the display substrate 100 included in the display apparatus may refer to the display substrate 100 provided in the above embodiment, and the repeated parts will not be described again.

It may be understood that the above embodiments are only exemplary embodiments for the purpose of illustrating the principles of the present disclosure, but the present disclosure is not limited to this. Those of ordinary skill in the art may also make several variations and improvements without departing from the spirit and essence of the present disclosure, which should be considered as the protection scope of the present disclosure.

1. A display substrate, comprising a base substrate and a circuit layer which is disposed on the base substrate, wherein the display substrate has an island area, a hole area and a bridge area;
the circuit layer comprises a driving circuit located in the island area, and a via hole located in the hole area; the circuit layer further comprises at least one photoelectric sensor that is electrically connected to the driving circuit; the photoelectric sensor comprises a first electrode layer, a photoelectric structure layer and a second electrode layer which are laminated; and
the photoelectric sensor is located in the island area, and the first electrode layer, the photoelectric structure layer and the second electrode layer of the photoelectric sensor are sequentially disposed in a direction pointing from the island area to the bridge area; and/or the photoelectric sensor is located in the bridge area, and the first electrode layer, the photoelectric structure layer and the second electrode layer of the photoelectric sensor are sequentially disposed in a direction pointing from the bridge area to the island area.

2. The display substrate according to claim 1, wherein the driving circuit comprises a first thin-film transistor configured to drive the photoelectric sensor, and an electrode which is one of a drain and a gate of the first thin-film transistor is electrically connected to the first electrode layer of the photoelectric sensor.

3. The display substrate according to claim 2, wherein the electrode which is one of the drain and the gate of the first thin-film transistor is multiplexed as the first electrode layer.

4-5. (canceled)

6. The display substrate according to claim 1, wherein a light-emitting device is disposed on a side of the circuit layer away from the base substrate; the light-emitting device comprises a third electrode layer, a fourth electrode layer, and a light-emitting layer disposed between the third electrode layer and the fourth electrode layer; and
the third electrode layer is multiplexed as the first electrode layer of the photoelectric sensor, and the fourth electrode layer is multiplexed as the second electrode layer of the photoelectric sensor.

7. The display substrate according to claim 1, wherein the photoelectric sensor is located in the island area; and the circuit layer comprises a first thin-film transistor located in the island area, and a buffer layer, a first insulator layer, a second insulator layer and a third insulator layer which are located in the island area and sequentially disposed on the base substrate;
the first thin-film transistor includes an active layer, a gate, a source and a drain; the active layer is disposed on a side of the buffer layer away from the base substrate; the first insulator layer is disposed on the side of the buffer layer away from the base substrate and covers the active layer of the first thin-film transistor; the gate of the first thin-film transistor is disposed on a side of the first insulator layer away from the base substrate, and orthographic projections of the gate of the first thin-film transistor and the active layer of the first thin-film transistor on the base substrate are at least partially overlapped; the source and the drain of the first thin-film transistor are disposed on a side of the second insulator layer away from the base substrate, the source is electrically connected to a source area of the active layer through a first connecting via hole that penetrates through the first insulator layer and the second insulator layer, and the drain is electrically connected to a drain area of the active layer through a second connecting via hole that penetrates through the first insulator layer and the second insulator layer; and
the photoelectric sensor is in the same layer with any one of the first insulator layer, the second insulator layer and the third insulator layer; or the photoelectric sensor is located between any adjacent two of the first insulator layer, the second insulator layer and the third insulator layer.

8. The display substrate according to claim 7, wherein the first electrode layer comprises a first sub-structure, a second sub-structure, and a third sub-structure connecting the first sub-structure and the second sub-structure; and
the first sub-structure, the third sub-structure and the second sub-structure are sequentially disposed in a direction pointing from the base substrate to the circuit layer.

9. The display substrate according to claim 8, wherein the first sub-structure is of an regular trapezoidal structure, the second sub-structure is of an inverted trapezoidal structure, and the third sub-structure is of a rectangular structure.

10. The display substrate according to claim 8, wherein the second sub-structure and the third sub-structure are electrically connected to the drain of the first thin-film transistor, and the drain of the first thin-film transistor is multiplexed as the second sub-structure and the third sub-structure; the first sub-structure is electrically connected to the third electrode layer, and the third electrode layer is multiplexed as the first sub-structure.

11. The display substrate according to claim 7, wherein the first electrode layer is configured as a rectangular structure.

12. The display substrate according to claim 1, wherein the photoelectric sensor is located in the island area, and the circuit layer comprises a buffer layer, a first insulator layer and a third insulator layer which are located in the bridge area and sequentially disposed on the base substrate; and
the photoelectric sensor is in the same layer as the first insulator layer or the third insulator layer; or, the photoelectric sensor is located between the first insulator layer and the third insulator layer.

13. The display substrate according to claim 12, wherein the driving circuit comprises a first thin-film transistor configured to drive the photoelectric sensor; and a third connecting via hole is formed in the first insulator layer; and
an electrode which is one of a drain and a gate of the first thin-film transistor is electrically connected to the first electrode layer through the third connecting via hole.

14. The display substrate according to claim 13, wherein the electrode which is one of the drain and the gate of the first thin-film transistor is multiplexed as the first electrode layer.

15-16. (canceled)

17. The display substrate according to claim 1, wherein the via hole in the hole area is located between the island area and the bridge area; the photoelectric sensor is located on a side wall of film layers between the island area and the bridge area; and the side wall is at a preset inclination angle to the base substrate.

18. The display substrate according to claim 1, wherein the via hole in the hole area is located between the island area and the bridge area; the photoelectric sensor includes a plurality of levels of photoelectric structures; the plurality of levels of photoelectric structures is located on a side wall of film layers between the island area and the bridge area;
a first photoelectric sub-structure of an i^{th}-level photoelectric structure is connected to a second photoelectric sub-structure of an (i−1)^{th}-level photoelectric structure; a second photoelectric sub-structure of the i^{th}-level photoelectric structure is connected to a first photoelectric sub-structure of an (i+1)^{th}-level photoelectric structure; 0<i≤N, where N is a positive integer greater than or equal to 2; and
an included angle between the first photoelectric sub-structure of the i^{th}-level photoelectric structure and the second photoelectric sub-structure of the (i−1)^{th}-level photoelectric structure ranges from 85° to 105°; an included angle between the second photoelectric sub-structure of the i^{th}-level photoelectric structure and the first photoelectric sub-structure of the (i+1)^{th}-level photoelectric structure ranges from 85° to 105°; and an included angle between the first photoelectric sub-structure of the i^{th}-level photoelectric structure and the second photoelectric sub-structure of the i^{th}-level photoelectric structure ranges from 85° to 105°.

19. A method for manufacturing a display substrate, the display substrate having an island area, a hole area and a bridge area, the method for manufacturing the display substrate comprising:
forming a circuit layer on a base substrate;
wherein the circuit layer comprises a driving circuit located in the island area, and a via hole located in the hole area; the circuit layer further comprises at least one photoelectric sensor that is electrically connected to the driving circuit, and the photoelectric sensor comprises a first electrode layer, a photoelectric structure layer and a second electrode layer which are laminated; and
the photoelectric sensor is located in the island area, and the first electrode layer, the photoelectric structure layer and the second electrode layer of the photoelectric sensor are sequentially disposed in a direction pointing from the island area to the bridge area; and/or the photoelectric sensor is located in the bridge area, and the first electrode layer, the photoelectric structure layer and the second electrode layer of the photoelectric sensor are sequentially disposed in a direction pointing from the bridge area to the island area.

20. A display apparatus, comprising the display substrate according to claim 1.

21. The display apparatus according to claim 20, wherein the driving circuit comprises a first thin-film transistor configured to drive the photoelectric sensor, and an electrode which is one of a drain and a gate of the first thin-film transistor is electrically connected to the first electrode layer of the photoelectric sensor.

22. The display apparatus according to claim 21, wherein the electrode which is one of the drain and the gate of the first thin-film transistor is multiplexed as the first electrode layer.

23. The display apparatus according to claim 20, wherein a light-emitting device is disposed on a side of the circuit layer away from the base substrate; the light-emitting device comprises a third electrode layer, a fourth electrode layer, and a light-emitting layer disposed between the third electrode layer and the fourth electrode layer; and
the third electrode layer is multiplexed as the first electrode layer of the photoelectric sensor, and the fourth electrode layer is multiplexed as the second electrode layer of the photoelectric sensor.

24. The display apparatus according to claim 20, wherein the photoelectric sensor is located in the island area; and the circuit layer comprises a first thin-film transistor located in the island area, and a buffer layer, a first insulator layer, a second insulator layer and a third insulator layer which are located in the island area and sequentially disposed on the base substrate;
the first thin-film transistor includes an active layer, a gate, a source and a drain; the active layer is disposed on a side of the buffer layer away from the base substrate; the first insulator layer is disposed on the side of the buffer layer away from the base substrate and covers the active layer of the first thin-film transistor; the gate of the first thin-film transistor is disposed on a side of the first insulator layer away from the base substrate, and orthographic projections of the gate of the first thin-film transistor and the active layer of the first thin-film transistor on the base substrate are at least partially overlapped; the source and the drain of the first thin-film transistor are disposed on a side of the second insulator layer away from the base substrate, the source is electrically connected to a source area of the active layer through a first connecting via hole that penetrates through the first insulator layer and the second insulator layer, and the drain is electrically connected to a drain area of the active layer through a second connecting via hole that penetrates through the first insulator layer and the second insulator layer; and
the photoelectric sensor is in the same layer with any one of the first insulator layer, the second insulator layer and the third insulator layer; or the photoelectric sensor is located between any adjacent two of the first insulator layer, the second insulator layer and the third insulator layer.
